(19) United States
(12) Patent Application Publication
(10) Pub. No.: US 2002/0086475 A1
(43) Pub. Date: Jul. 4, 2002

(54) Zero overlap contact/via with metal plug

(76) Inventor: Robert H. Havemann, Garland, TX (US)

Correspondence Address: TEXAS INSTRUMENTS INCORPORATED, P O BOX 655474, M/S 3999, DALLAS, TX, 75265

(21) Appl. No.: 10/006,639

(22) Filed: Nov. 8, 2001

Related U.S. Application Data
(60) Provisional application No. 60/277,535, filed on Mar. 21, 2001.
(60) Provisional application No. 60/259,314, filed on Dec. 31, 2000.

(51) Int. Cl. H01L 21/8238

(52) U.S. Cl. 438/200

(57) ABSTRACT

A metallization interconnect structure where the bottom layer of the interlevel section has etch selectivity with respect to the layer beneath it, which in the preferred embodiment is the cap layer of a metallization layer. The etch selectivity allows the dielectric material surrounding the metallization line to be preserved and protected from overetch, which can erode the dielectric material surrounding the metallization line and cause a cavity.

### BACKGROUND AND SUMMARY OF THE INVENTION

The present invention relates to integrated circuit structures and fabrication methods, and particularly to interconnect fabrication.

### Background

Metals are used in microelectronics as a means of supplying power and transmitting electricity from one place to another. The application of metal and metal-like layers is called metallization.

Metallization structures usually include several levels of materials. Metallization lines or interconnects are surrounded by dielectric material and are connected to other levels of metallization lines by vias. Such structures have recently been produced effectively using the damascene or dual damascene process.

Etching is critical to the dual-damascene process. Trenches are etched through the dielectric material to connect different metal levels by vias. The placement of the vias is controlled by the etch patterns, which are placed using photolithography. Though the accuracy of such methods is good, perfect positioning is not always accomplished. This can create problems when etches are performed, because materials that are not intended to be exposed to an etchant can sometimes be exposed.

Overetch of zero-overlap vias can produce erosion of the dielectric material surrounding the metal interconnect lines. This erosion is a problem because it can produce an angular cavity next to the copper metallization, which the barrier layer may be unable to fill. Incomplete coverage by the barrier layer means that copper contamination can occur. This is particularly a problem with low-k dielectrics, because if the overetch penetrates the cap dielectric, the cavity in the low-k dielectric (where the etch rate is much higher) may be jagged and/or very large.

### Zero Overlap Contact/Via With Metal Plug

The present application discloses an improvement to interconnect technology. In the preferred embodiment, the intralevel dielectric structure has added to it a bottom layer of material that can be selectively etched with respect to the top layer, or cap layer, of material on the metallization level beneath. This selectivity allows the via to be fully etched, allowing the full cross section of metal to via connection, without eroding the dielectric material next to the metal line in the metallization level.

Advantages of the disclosed methods and structures, in various embodiments, can include one or more of the following:

better via diffusion barrier coverage;

better margin for etch endpoint of top of metallization layer;

protective cap for low k dielectric during chemical mechanical polish and wet processing;

protective cap for underlying low k dielectric during via spatter etch clean (performed in situ prior to barrier metal deposition);

can offer added advantage of better adhesion of dielectric diffusion barrier by providing a buffer between underlying low k dielectric and diffusion barrier.

### BRIEF DESCRIPTION OF THE DRAWINGS

The disclosed inventions will be described with reference to the accompanying drawings, which show important sample embodiments of the invention and which are incorporated in the specification hereof by reference, wherein:

FIG. 1 shows two levels of a metallization interconnect structure.

FIG. 2 shows a detail of the interconnect structure that demonstrates the preferred embodiment.

FIG. 3 shows overetch consequences in a conventional design.

FIG. 4 shows another view of the interconnect structure showing filled vias.

FIG. 5 shows a variation on the preferred embodiment having a second cap layer.

### DETAILED DESCRIPTION OF THE PREFERRED EMBODIMENTS

The numerous innovative teachings of the present application will be described with particular reference to the presently preferred embodiment. However, it should be understood that this class of embodiments provides only a few examples of the many advantageous uses of the innovative teachings herein. In general, statements made in the specification of the present application do not necessarily delimit any of the various claimed inventions. Moreover, some statements may apply to some inventive features but not to others.

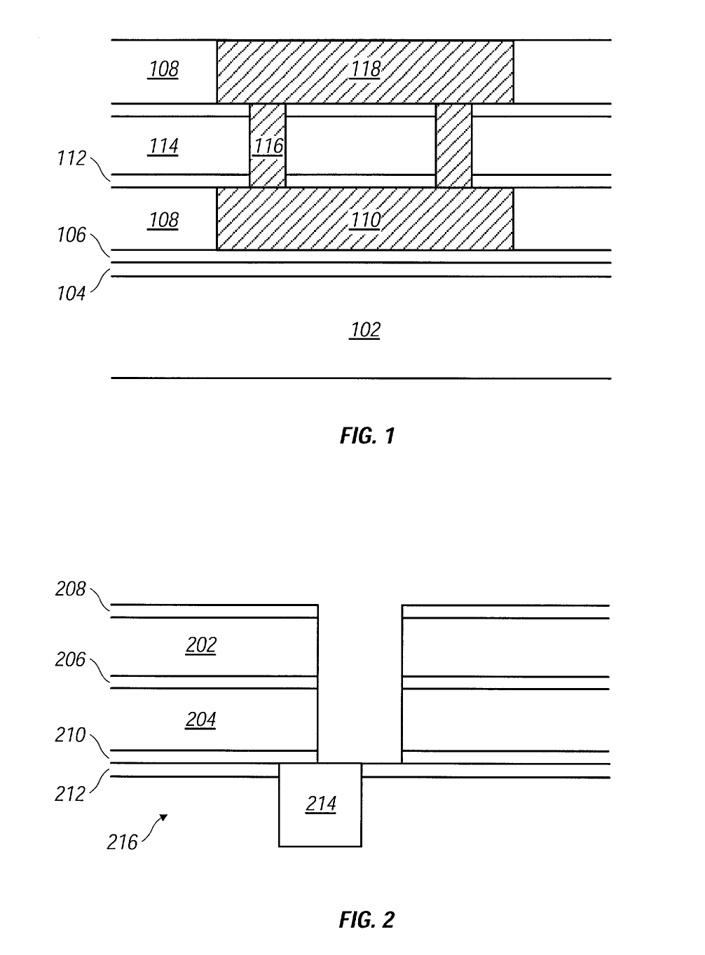

FIG. 1 shows a partially fabricated integrated circuit interconnect structure. A substrate 102 is covered by a layer of oxide 104, which is covered by a thin layer (about 100 nm) of nitride 106. A layer of intrametal dielectric 108 is then deposited, and a trench is etched therein for deposition of the metallization line 110. This is planarized and covered by a thin layer (100 nm) of carbide 112. In a typical damascene process, this carbide layer is covered with an interlevel dielectric 114, another carbide layer, and another layer of intrametal dielectric material 108. In the via first damascene approach, holes for vias 116 for connecting different metallization layers are etched through the existing layers down to the metallization level below. The trench for the next metallization level is then etched. The via holes are lined with a diffusion barrier material and filled with metal, as is the metallization trench. The vias connect the two shown metallization levels 110, 118.

As discussed above, the total metallization structure typically comprises multiple levels of metal lines separated by dielectric material, the metal of different levels being connected by vias. The dielectric material between the metallization lines, in the same level as those lines, is called intrametal dielectric material (IMD). The dielectric above and below the metallization levels surrounds the vias that connect metallization levels. This material is called the interlevel dielectric material (ILD).

FIG. 2 shows an end-on view of a metallization structure according to the preferred embodiment. The interlevel dielectric stack is modified to add a hard layer of etch stopping material to the bottom, layer 210 in the figure. This layer can be selectively etched with respect to the underlying cap layer of the metallization level.

The ILD has its own substructure comprising different sub-levels of dielectric material 202, 204 separated by a trench etch stop layer of SiC 206. This layer overcomes etch nonuniformity and provides a clear stopping point for the trench etch to avoid different trench depths from etch microloading. In some embodiments this layer also protects the ILD from damage during subsequent processing such as via spatter etch clean.

SiC is used as the ILD etch stop layer. As shown in FIG. 2, the top of the ILD begins with a layer of SiC 208, followed by a low k dielectric 202, followed by another layer of SiC 206 atop another layer of low k dielectric 204.

At the bottom of the ILD structure is located a bottom layer of material 210, such as SiN or SiCN, which has an etch selectivity relative to the layer beneath 212 (which forms the top layer of the next metallization level in the preferred embodiment). The top layer of the metallization level is typically a layer of SiC.

A copper metallization line 214 (seen end on in this figure) is formed in a dielectric material 216 at the metal interconnect level. The metal level includes this intrametal dielectric material 216, and the cap layer 212 to serve as an etch stop during the via etch process.

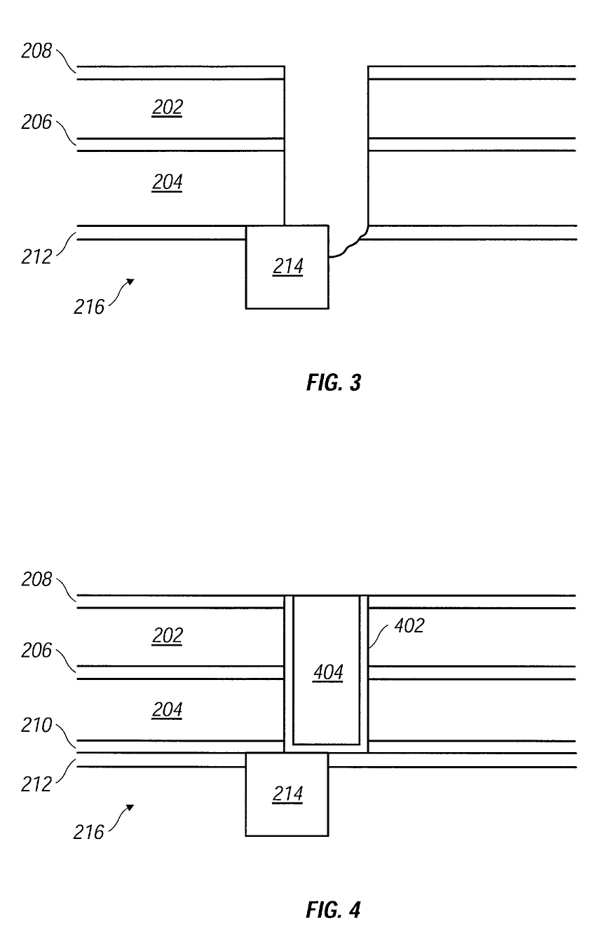

Due to misalignment of the via and the metal line, the via contact trench may be offset from the metal line and partly overlap the corner of the cap layer. (Note misalignment of photolithographic patterns is a common occurrence with tolerance in the +/−100 nm range for current steppers/scanners.) During etching of the via trench, overetch will cause this corner to become jagged and uneven, which causes problems with the coverage of the diffusion barrier that will be formed to line the via trench's bottom and sidewalls. FIG. 3 shows a conventional metallization structure exhibiting this problem. The interlevel dielectric material 202, 204, is etched down to the metallization level, and the cap dielectric 212 serves as an etch stop. If the cap dielectric 212 is etched through, the much more easily etched low k dielectric beneath 216 is eroded, forming a cavity next to the metallization line. This cavity causes problems when the barrier lining is deposited on the walls and bottom of the via, causing incomplete coverage. Incomplete coverage allows the copper to diffuse into surrounding regions altering electric properties in undesirable ways.

In the preferred embodiment, the via width is designed to be 0.25 micron. The depth before damascene trench cut and nitride open etch at the bottom of the via is 1.0 micron. The SiC cap layer on the metallization layer is 100 nm thick. Both the top low k dielectric thickness is 400 nm, and the intermediate SiC layer is 100 nm thick. The bottom stop layer, made from SiCN or SiN (or another material with sufficiently different etch selectivity than SiC) thickness is 100 nm thick. The barrier metal thickness that lines the vias is 25 nm of Ta or TaN. The thickness along the walls will depend on the deposition method and step coverage can be from 20% to 100% of this thickness. In the preferred embodiment, the vias and the metallization lines are made from damascene copper.

FIG. 4 shows the innovative interconnect structure after the vias have been filled. The passivation layer 402 is shown covering the inside walls of the via cavity. This layer is typically made from Ti/TiN for a tungsten or aluminum plug, or TiN(Si), WN, Ta, or TaN for copper plugs, for example. Other materials are possible depending on the particular process used, of course. The via metal 404 is also shown filling the cavity. Use of the present innovations can offer the added advantage of better adhesion of the dielectric diffusion barrier 402 by providing a buffer between the underlying low-k dielectric and the diffusion barrier.

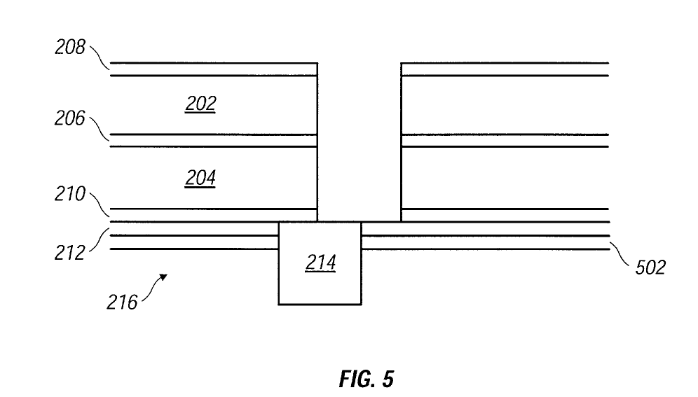

FIG. 5 shows another embodiment for the present innovations. beneath the cap layer 212 there is located another cap layer 502. This second cap layer can serve as additional overetch protection for the IMD material 216, preventing erosion of the IMD during etch. The added cap layer can also be used to promote adhesion for the diffusion barrier that is later deposited in the via trench. This layer can be of the same material as the first cap layer, or of different material to provide some added selectivity during etch or better adhesive properties.

### Definitions

Following are short definitions of the usual meanings of some of the technical terms which are used in the present application. (However, those of ordinary skill will recognize whether the context requires a different meaning.) Additional definitions can be found in the standard technical dictionaries and journals.

ILD: Interlevel dielectric, the dielectric material filling the via levels between via lines.

IMD: Intrametal dielectric, the dielectric material filling the metal levels between interconnect lines.

### Modifications and Variations

As will be recognized by those skilled in the art, the innovative concepts described in the present application can be modified and varied over a tremendous range of applications, and accordingly the scope of patented subject matter is not limited by any of the specific exemplary teachings given, but is only defined by the issued claims.

The cap layer and the etch stop layers can be made from different materials on different levels of the metallization structure. This means that at one juncture, the cap layer and the etch-stop layer directly above it may be made from a set of materials, but on the next iteration of that structure (where the multiple metallization levels repeat themselves) they may be made from a different set of materials. The particular materials used do not limit the innovations, and this application contemplates a range of possible materials that can implement the ideas herein described.

Porous organic and/or inorganic materials may be used, especially for the dielectric materials. The IMD material may differ form the ILD material.

While the via first dual damascene integration method is shown in the examples given, other integration schemes such as trench first, half via first, and dual top hard mask schemes may also be used.

It should also be noted that the number of layers of metallization described above does not implicitly limit any of the claims, which can be applied to processes and structures with more or fewer layers.

Similarly, it will be readily recognized that the described process steps can also be embedded into hybrid process flows, such as system on a chip (SOC), or BiCMOS or smart-power processes.

The teachings above are not necessarily strictly limited to silicon. In alternative embodiments, it is contemplated that these teachings can also be applied to structures and methods using other semiconductors, such as silicon/germanium and related alloys, gallium arsenide and related compounds and alloys, indium phosphide and related compounds, and other semiconductors, including layered heterogeneous structures.

The present teachings are also applicable for fabricating optical waveguides, where the trench is filled with another dielectric rather than a conductor. The same innovative principles form this application can be applied in this context as well.

It should also be noted that, over time, an increasing number of functions tend to be combined into a single chip. The disclosed inventions can still be advantageous even with different allocations of functions among chips, as long as the functional principles of operation described above are still observed.

Additional general background, which help to show the knowledge of those skilled in the art regarding variations and implementations of the disclosed inventions, may be found in the following documents, all of which are hereby incorporated by reference: Coburn, PLASMA ETCHING AND REACTIVE ION ETCHING (1982); HANDBOOK OF PLASMA PROCESSING TECHNOLOGY (ed. Rossnagel); PLASMA ETCHING (ed. Manos and Flamm 1989); PLASMA PROCESSING (ed. Dieleman et al. 1982); Schmitz, CVD OF TUNGSTEN AND TUNGSTEN SILICIDES FOR VLSI/ULSI APPLICATIONS (1992); METALLIZATION AND METAL-SEMICONDUCTOR INTERFACES (ed. Batra 1989); VLSI METALLIZATION: PHYSICS AND TECHNOLOGIES (ed. Shenai 1991); Murarka, METALLIZATION THEORY AND PRACTICE FOR VLSI AND ULSI (1993); HANDBOOK OF MULTILEVEL METALLIZATION FOR INTEGRATED CIRCUITS (ed. Wilson et al. 1993); Rao, MULTILEVEL INTERCONNECT TECHNOLOGY (1993); CHEMICAL VAPOR DEPOSITION (ed. M. L. Hitchman 1993); and the semiannual conference proceedings of the Electrochemical Society on plasma processing.

What is claimed is:

1. A method for fabricating vias, comprising the steps of:
(a.) etching, at a patterned via location, through a dielectric cap layer which has a first composition;
(b.) etching, at said location, through a layer of low-k dielectric material under said cap layer;
(c.) etching, at said location, through a bottom layer of etchstopping dielectric material under said layer of low-k dielectric material, to thereby expose an underlying metallization line which is laterally surrounded by another instance of said cap layer;
wherein said etching step (b.) is selective to said bottom layer, and
wherein said etching step (c.) is selective to said cap layer.

2. The method of claim 1, wherein said bottom layer is made of SiN.

3. The method of claim 1, wherein said bottom layer is made of SiCN.

4. The method of claim 1, wherein said cap layer is made of SiC.

5. The method of claim 1, wherein said low-k dielectric is an inorganic material.

6. The method of claim 1, wherein said low-k dielectric is an inorganic material.

7. The method of claim 1, further comprising a second cap layer located beneath said cap layer.

8. An integrated circuit structure, comprising:
a first level comprising a metal interconnect line embedded within a low-k dielectric material, said level having a cap layer over said low-k material;
a second level comprising a low-k dielectric material and having a bottom layer thereunder;
wherein said cap layer underlies said bottom layer; and
wherein said bottom layer is selectively etched with respect to said cap layer.

9. The method of claim 8, wherein said bottom layer is made of SiN.

10. The method of claim 8, wherein said bottom layer is made of SiCN.

11. The method of claim 8, wherein said cap layer is made of SiC.

12. The method of claim 8, further comprising a second cap layer located beneath said cap layer, wherein said bottom layer can be selectively etched with respect to said second cap layer.

13. An integrated circuit structure, comprising:
a metal interconnect structure having a first level and a second level, wherein said first level comprises a low-k dielectric, metal interconnect lines, and a cap layer;
wherein said second level comprises a low-k dielectric material, interconnect vias, and a bottom layer;
wherein said cap layer and said bottom layer both have higher densities than said low-k dielectric; and
wherein said first and said second levels are positioned such that said bottom layer of said second level overlies said cap layer of said first level.

14. The method of claim 13, wherein said bottom layer is made of SiN.

15. The method of claim 13, wherein said bottom layer is made of SiCN.

16. The method of claim 13, wherein said low-k dielectric is made of an inorganic material.

17. The method of claim 13, wherein said low-k dielectric is made of an organic material.

18. The method of claim 13, further comprising a second cap layer located beneath said cap layer, said second cap layer having higher density than said low-k dielectric.

19. An integrated circuit structure, comprising:
a metal interconnect structure having a first level and a second level, wherein said first level comprises a low-k dielectric, metal interconnect lines, and a cap layer;
wherein said second level comprises a low-k dielectric material, interconnect vias, and a bottom layer;
wherein said bottom layer can be selectively etched with respect to said cap layer; and
wherein said first and said second levels are positioned such that said bottom layer of said second level overlies said cap layer of said first level.

20. The method of claim 19, wherein said bottom layer is made of SiN.

21. The method of claim 19, wherein said bottom layer is made of SiCN.

22. The method of claim 19, further comprising a second cap layer located beneath said cap layer, wherein said bottom layer can be selectively etched with respect to both said cap layer and said second cap layer.
